(19) United States
(12) Patent Application Publication
(10) Pub. No.: US 2015/0372160 A1
(43) Pub. Date: Dec. 24, 2015

(54) P-TYPE DOPANT AND METHOD FOR P-TYPE DOPING OF A SEMICONDUCTOR

(71) Applicant: NANYANG TECHNOLOGICAL UNIVERSITY, Singapore (SG)

(72) Inventors: Chia Sern CHAN, Singapore (SG); Shuyan XU, Singapore (SG); Jian Wei Mark LIM, Singapore (SG)

(21) Appl. No.: 14/745,049

(22) Filed: Jun. 19, 2015

(30) Foreign Application Priority Data
Jun. 20, 2014 (SG) 10201403455T

(51) Int. Cl. H01L 31/0288; H01L 31/0352; H01L 31/18

(52) U.S. Cl. CPC H01L 31/0288; H01L 31/1804; H01L 31/03529

(57) ABSTRACT

A p-type dopant for a Group IV semiconductor, the p-type dopant comprising at least: a mixture of nitrogen and phosphorous configured for plasma ion implantation on the Group IV semiconductor. A method of p-type doping of a Group IV semiconductor; the method comprising the steps of: a) dissociating and ionizing a feedstock comprising a mixture of nitrogen and phosphorous a using an input power; and b) applying a bias onto a support for the Group IV semiconductor so that ions from the ionized nitrogen and phosphorous are attracted to and implanted on a surface of the Group IV semiconductor.

### CROSS REFERENCE TO RELATED APPLICATIONS

This applications claims priority to Singapore Application No. 10201403455T filed on Jun. 20, 2014 and entitled “P-TYPE DOPANT AND METHOD OF P-TYPE DOPING OF A SEMICONDUCTOR”, which is incorporated herein by reference in its entirety for all purposes.

### FIELD OF THE INVENTION

This invention relates to a p-type dopant and method of p-type doping of a semiconductor.

### BACKGROUND OF THE INVENTION

Conventional dopants for Group IV semiconductors (such as carbon, silicon, germanium, silicon carbide, and silicon germanium) are acceptors from Group III elements (such as boron and gallium) or donors from Group V elements (such as arsenic and phosphorus). By doping the intrinsic Group IV semiconductors with Group V elements, substitutional Group V donors will generate extra valence electrons, making the semiconductor electrically conductive and “n-type” (where the electron concentration is larger than the hole concentration at thermal equilibrium). On the other hand, doping Group IV semiconductors with Group III elements will create holes and result in an electrically conductive p-type semiconductor (where the hole concentration is larger than the electron concentration at thermal equilibrium). A p-n junction with a built-in electric field will be formed when a p-type semiconductor and an n-type semiconductor are placed in junction with one another. The electric field is pointing from the n-type to the p-type semiconductor. The p-n junction is the most essential element for most semiconductor electronic devices such as diodes, transistors and solar cells.

A typical p-type crystalline silicon solar cell comprises at least an n-type emitter (fabricated using ion implantation or diffusion, followed by a thermal annealing process) on the front side of the p-type silicon wafer forming a p-n junction. The open circuit voltage of the solar cell is governed by the built-in electric field across the p-n junction. To suppress the Schottky junction at the metal contact on the rear side of the p-type silicon wafer, a heavily doped p-type layer has to be produced at the metal contact. This can be realized either by the conventional boron-doping or the high temperature aluminium-silicon alloying process. Heavily doping the Group III acceptors in the lightly-doped p-type semiconductor will improve conductivity but the resulting p⁺-p junction will not induce additional built-in electric field unless a further alloying process takes place or a p-type heterojunction is formed (i.e. P⁺-p junction).

To date, the photovoltaic industry is moving toward the fabrication of high-efficiency crystalline silicon solar cells in which the rear surface has to be partially passivated by a dielectric layer (such as SiOₓ, Al₂O₃, etc.). The subsequent high temperature firing process for forming Al—Si alloy would deteriorate the passivation quality of the dielectric layer.

### SUMMARY OF INVENTION

A p-type dopant and method for fabrication of a unique p-type doping layer on a semiconductor is disclosed. The method can be employed to form not only a good ohmic contact but also an additional built-in electric field at rear surface of p-type crystalline silicon solar cells which improves the open-circuit voltage of the solar cells. This can be potentially employed to eliminate the high temperature Al—Si alloying process in the manufacturing of high efficiency silicon solar cells.

The method comprises forming a “heterojunction-like” p-type doping on a Group IV semiconductor and requires at least a nitrogen-and-phosphorous containing mixture as the doping source. Both nitrogen and phosphorous are Group V elements and they are considered as the n-type dopants for Group IV semiconductors (such as silicon). The method is a unique synergy using the nitrogen and phosphorous sources to produce an unexpected p-type doping effect on the Group IV semiconductors. Unlike conventional Group III p-type dopants (such as boron), the unique p-type dopant can induce an additional built-in electric field on the p-type semiconductors (such as boron-doped silicon) which points from the p-type semiconductor to the dopant layer.

One application is to use this unique dopant, instead of conventional boron doping, for forming a back surface field and an ohmic contact on the rear side of p-type crystalline silicon solar cells, and therein the open-circuit voltage of the solar cells can be improved. The improvement in open circuit voltage depends on the composition of the unique mixture.

Also, one-step dual-side formation of the n-type emitter and the p-type back surface field is enabled since both processes involve the use of the phosphorous dopant. The unique doping method can eliminate the high-temperature aluminum-silicon alloying process which could deteriorate the passivation quality of the dielectric layer in high efficiency crystalline silicon solar cells.

According to a first aspect, there is provided a p-type dopant for a Group IV semiconductor, the p-type dopant comprising at least: a mixture of nitrogen and phosphorous configured for plasma ion implantation on the Group IV semiconductor.

The phosphorous may be provided in the form of gaseous phosphine (PH₃) and the nitrogen may be provided in the form of gaseous nitrogen (N₂).

Percentage of nitrogen in the p-type dopant may range from 50% to 95.24%.

The Group IV semiconductor may be a p-type semiconductor and the p-type dopant forms a dopant layer on the p-type semiconductor such that an electric field is induced in the p-type semiconductor, the electric field pointing from the p-type semiconductor to the dopant layer.

The Group IV semiconductor may comprise silicon.

According to a second aspect, there is provided a method of p-type doping of a Group IV semiconductor; the method comprising the steps of: a) dissociating and ionizing a feedstock comprising a mixture of nitrogen and phosphorous a using an input power; and b) applying a bias onto a support for the Group IV semiconductor so that ions from the ionized nitrogen and phosphorous are attracted to and implanted on a surface of the Group IV semiconductor.

The input power may range from 2 kW to 3 kW.

The bias may range from 150V to 600V.

The phosphorous may be provided in the form of gaseous phosphine and the nitrogen may be provided in the form of gaseous nitrogen.

The Group IV semiconductor may be a p-type silicon layer.

According to a third aspect, there is provided a Group IV semiconductor device comprising: a Group IV semiconductor layer; a p-type dopant layer formed on the Group IV semiconductor layer using a dopant comprising a mixture of nitrogen and phosphorous, the p-type dopant layer having shallow-level acceptor complexes contributing holes and a widened bandgap compared to the Group IV semiconductor layer.

The Group IV semiconductor layer may comprise a silicon layer and the p-type dopant layer has no significant decrease in silicon density compared to the silicon layer.

The Group IV semiconductor device may be a silicon solar cell, the Group IV semiconductor layer may be a p-type crystalline silicon layer and the p-type dopant layer may form an electric field and an ohmic contact on the p-type crystalline silicon layer.

Alternatively, for all aspects, the Group IV semiconductor may be an n-type semiconductor and the p-type dopant introduces band bending to the n-type Group IV semiconductor causing heterojunction band structures.

### BRIEF DESCRIPTION OF FIGURES

In order that the invention may be fully understood and readily put into practical effect there shall now be described by way of non-limitative example only exemplary embodiments of the present invention, the description being with reference to the accompanying illustrative drawings.

FIG. 1 is a graph of SIMS analysis of the depth profile of silicon doped by phosphorus only

FIG. 2 is a graph of SIMS analysis of the depth profile of silicon co-doped by phosphorus and nitrogen under the same experimental conditions as that of the doping in FIG. 1.

FIG. 3 is a schematic illustration of structure of crystalline silicon cells after unique p-type doping at a rear side.

FIG. 4 is a graph of resistance of the p-type doped rear silicon surface and change in Voc with variation of input power.

FIG. 5 is a graph of resistance of the p-type doped rear silicon surface and change in Voc with variation of bias.

FIG. 6 is a graph of resistance of the p-type doped rear silicon surface and change in Voc with nitrogen percentage in the gas mixture.

FIG. 7 is a graph of resistance of the p-type doped rear silicon surface and change in Voc using different types of dopants.

### DETAILED DESCRIPTION

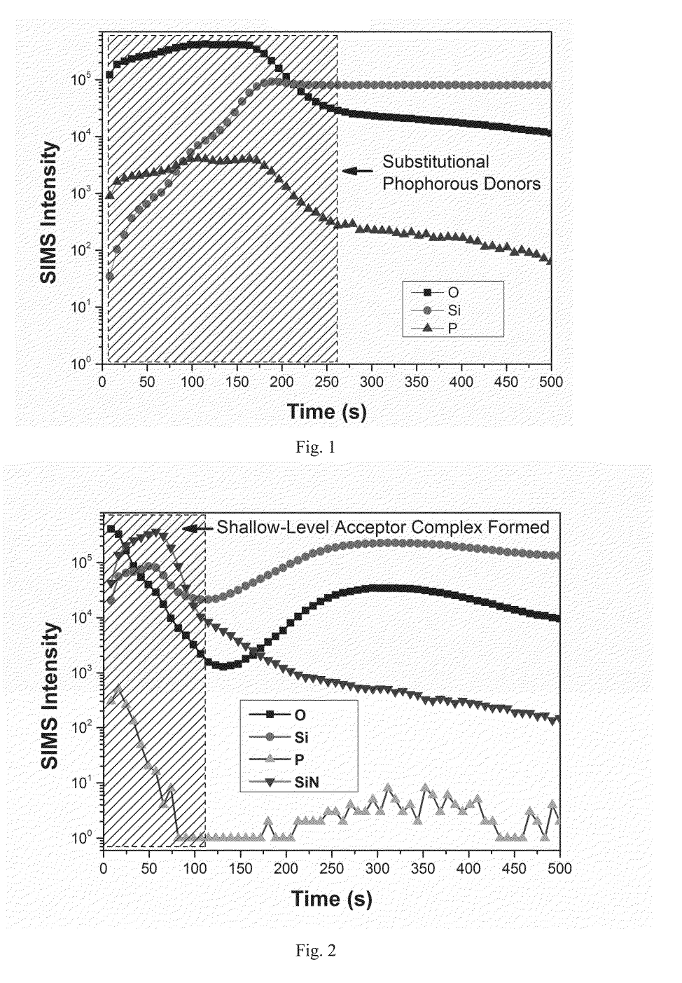

Exemplary embodiments of a p-type dopant and method of doping a p-type semiconductor will be described below with reference to FIGS. 1 to 7.

The method of doping a p-type semiconductor comprises forming a “heterojunction-like” p-type doping on a Group IV semiconductor such as silicon. The method uses at least a nitrogen-and-phosphorous containing mixture as the doping source.

Although both nitrogen and phosphorous are Group V elements and therefore normally considered as n-type dopants for Group IV semiconductors, in the present method, the nitrogen and phosphorous sources produce an unexpected p-type doping effect on the Group IV semiconductors. Unlike conventional Group III p-type dopants (such as boron), the unique p-type dopant of the present method, comprising phosphorous and nitrogen, can induce an additional built-in electric field in the p-type semiconductors (such as boron-doped silicon) which points from the p-type semiconductor to the dopant layer.

Doping a silicon lattice with only phosphorous results in formation of substitutional donors (which contribute electrons) and interstitial deep-level defects (which trap the carriers). By contrast, the present method of co-doping a silicon lattice with phosphorous and nitrogen results in formation of shallow-level acceptor complexes which contributes holes and at the same time widens the bandgap in addition to other deep-level defects.

Secondary ion mass spectrometry (SIMS) was used to analyze the doping profile of silicon by sputtering the silicon surface with a focused primary ion beam and collecting and analyzing ejected secondary ions. When doping with only phosphorus, the incident phosphorous kicked out silicon atoms resulting in a decrease of silicon density near the surface and the formation of the substitutional donor, as shown in FIG. 1.

However, in the present method of co-doping using phosphorus and nitrogen under the same experimental conditions, complexes were formed instead resulting in no significant decrease in silicon density near the surface, as shown in FIG. 2. Thus, by co-doping with phosphorus and nitrogen on n-type silicon wafer, rectification effect was observed from its voltage-current characteristics, showing that there is a p-n junction formed. Hence, the unique complexes formed belong to shallow-level acceptors.

One of the applications of the present method is to use the unique dopant of phosphorous and nitrogen, instead of conventional boron-only doping, for forming a back surface field and an ohmic contact on the rear side of p-type crystalline silicon solar cells, as will be described in greater detail in the Example below. In this way, the open-circuit voltage can be improved. The present doping method can eliminate the high-temperature aluminium-silicon alloying process which could deteriorate the passivation quality of the dielectric layer in high efficiency crystalline silicon solar cells. Also, one-step dual-side formation of the n-type emitter and the p-type back surface field is enabled since both processes involve the use of the phosphorous dopant.

### EXAMPLE

### Unique p-Type Doping on Rear Surface of Silicon Solar Cell by Plasma Ion Implantation

A 500 kHz rf driven source, with dynamic power output of 50-3500 W, was utilized to drive a flat spiral coil through a matching network. Highly-uniform, non-equilibrium, Inductively Coupled Plasma (ICP) with electron density ranging from 10¹¹-10¹³ cm⁻³ was generated in a stainless-steel-walled cylindrical vacuum chamber with a diameter of 30 cm and a height of 20 cm to dissociate and ionize nitrogen and phosphine feedstock gases. A negative bias was applied onto the substrate holder holding silicon solar cells to attract the ions for implantation. The implanted depth of the dopants is governed by the magnitude of the bias applied to the substrate holder. The doping dose is controlled by the implantation time, bias and input power.

The input power range is dependent on the electrode design and volume of dopant discharge generated. The dissociation and ionization of feedstock depend on the electron energy. The electron energy in the plasma has to be higher than the threshold energy of dissociation and ionization. Use of other plasma (such as Capacitively Coupled Plasma, Microwave Plasma, etc.) is possible if the electron energy can be controlled to reach the required threshold energy.

The unique p-type doping was carried out on the rear surface 22 of the silicon solar cells 10. Prior to the doping or ion implantation, the silicon solar cells had undergone a standard raw-damage removal, surface texturing, thermal diffusion, SiNₓ antireflective coating and local metallization on their front sides 11.

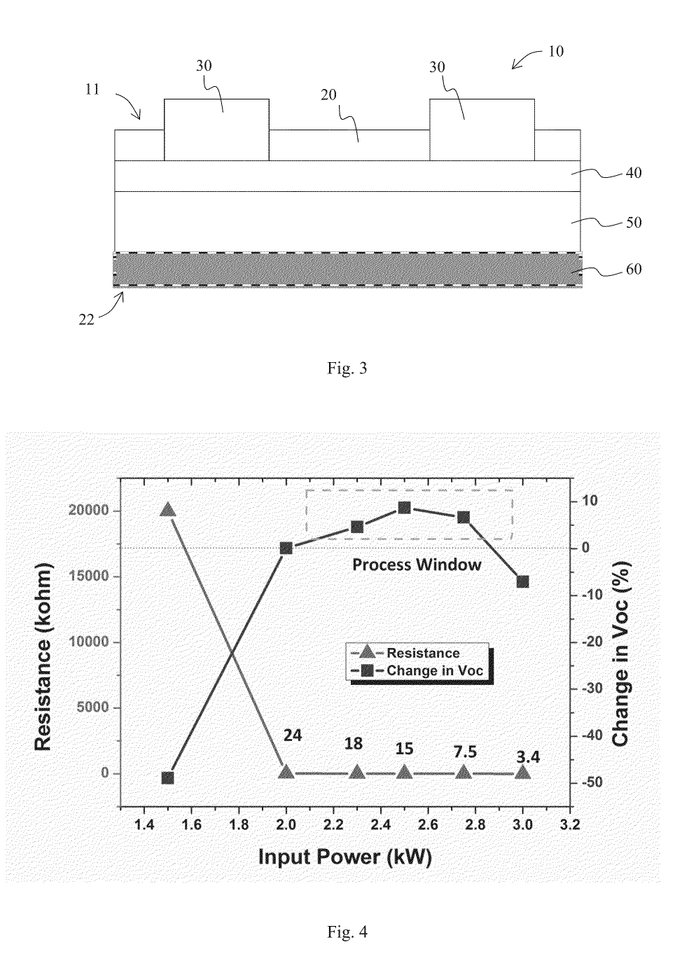

The structure of the solar cells 10 after the unique p-type doping at the rear side is shown in FIG. 3. As can be seen, the p-type doped solar cells 10 each comprise a SiNₓ antireflective coating 20 on the front side 11 with Ag (silver) contacts 30 metallized thereon, an n-type diffusion layer 40 adjacent the antireflective coating 20, a p-type crystalline silicon wafer 50 adjacent the diffusion layer 40, and the unique p-type doping layer 60 formed using the present method on the silicon wafer 50 on the rear side 22 of the solar cells 10.

The resistance of the unique p-type doping layer 60 at the rear side 22 of silicon solar cell 10 was measured by a multimeter with 1 cm space between the measuring electrodes. The performance of the solar cells 10 was characterized by the standard Sun Voc equipment.

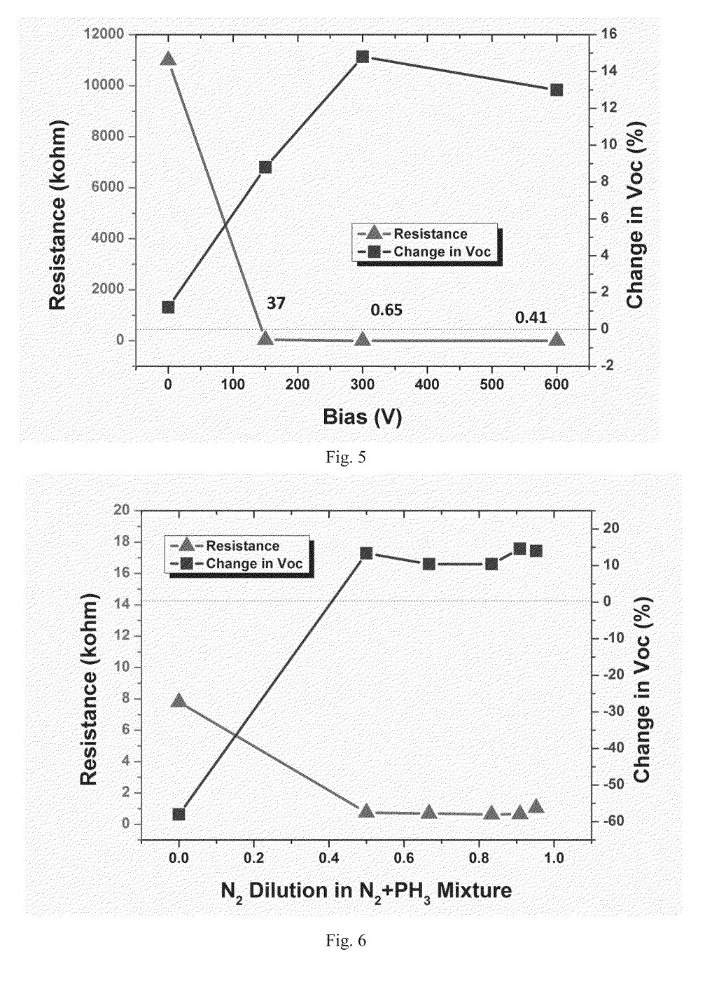

The process window for the unique p-type doping was investigated through an experimental series in which input power (FIG. 4), bias (FIG. 5) and nitrogen percentage in the gas mixture (FIG. 6) were varied. As can be seen in the figures, the unique p-type doping layer 60 is capable of improving not only the conductance of the rear 22 silicon surface (forming ohmic metal contact) but also the open circuit voltage (Voc) of the solar cells 10 (due to the built-in electric field). Such a result will not be achieved by conventional ion implantation using borane (B₂H₆), nitrogen (N₂) or phosphine (PH₃) feedstock gas individually. It can also be seen from FIG. 6 that the percentage of nitrogen in the doping gas mixture can range between 50 to 95.24% without significantly affecting the improvement in conductance and Voc of the doped solar cells 10.

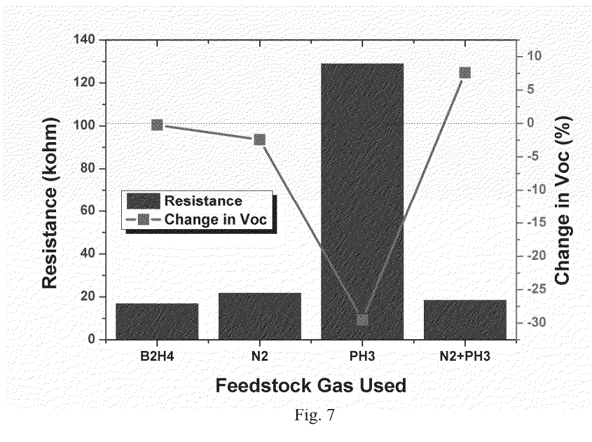

In FIG. 7, it can be seen that doping with only boron (Group III element) can improve only the conductivity of the rear silicon surface but not the Voc. On the other hand, doping with only phosphorus (Group V element) will result in a p-n junction formed at the rear surface where the built-in electric field is pointing from the phosphorus-doped layer to p-type silicon wafer. This will therefore deteriorate the Voc of the p-type silicon solar cells.

### Commercial Applications of the Invention

The unique p-type dopant and doping method of the present invention can be employed in the fabrication of most semiconductor electronic devices such as diodes, transistors and solar cells. The photovoltaic industry can utilize this unique dopant, instead of conventional boron doping, for forming a back surface field and an ohmic contact on the rear side of p-type crystalline silicon solar cells. This can further improve the open-circuit voltage of the solar cells and eliminate the high temperature Al—Si alloying process which would deteriorate the passivation quality of the dielectric layer.

Whilst there has been described in the foregoing description exemplary embodiments of the present invention, it will be understood by those skilled in the technology concerned that many variations in details of design, construction and/or operation may be made without departing from the present invention. For example, instead of silicon, the present dopant and method can also be applied to other Group IV semiconductors such as diamond, silicon, germanium, silicon carbide, silicon germanium, etc. The magnitude and direction of the built-in electric field depends on the bandgap and Fermi level of the semiconductor (i.e. band bending).

For the Group IV semiconductors, the most common p-type and n-type dopants are Group III (such as boron, gallium, etc.) and Group V elements (such as phosphorus, arsenic, etc.) respectively. The present method can thus also be used to produce similar effect on other Group IV semiconductors besides silicon.

Dopants also have the important effect of shifting the energy bands relative to the Fermi level (i.e. band bending). The p-n junction's properties are due to the band bending. Thus, not only can the dopants be used for p-type Group IV semiconductors, the dopants will also introduce band bending to n-type Group IV semiconductors, causing heterojunction band structures.

Besides phosphine gas, other phosphorous-containing sources include phosphorus solid targets. Besides nitrogen gas, other nitrogen-containing sources include ammonia gas.

The major plasma parameters to fabricate p-type characteristics are electron density and electron temperature. The electron energy should be higher than the threshold energy to dissociate and ionize the feedstock. If solid target is used, the sputtering force must be strong enough to sputter the solid clusters from the target. The clusters need to be atomized and ionized via strong impulsive plasma fragmentation process before being implanted onto the substrates.

Although the range of percentage of nitrogen in the practical experiments performed was between 50%-95.24%, as long as there is presence of nitrogen and and phosphorus (e.g. in the form of phosphine) in the doping feedstock gas mixture, there will be a possibility of obtaining a p-type characteristic in the doped substrate.

What is claimed is:

1. A p-type dopant for a Group IV semiconductor, the p-type dopant comprising at least: a mixture of nitrogen and phosphorous configured for plasma ion implantation on the Group IV semiconductor.

2. The p-type dopant of claim 1, wherein the phosphorous is provided in the form of gaseous phosphine (PH₃) and the nitrogen is provided in the form of gaseous nitrogen (N₂).

3. The p-type dopant of claim 1, wherein percentage of nitrogen in the p-type dopant ranges from 50% to 95.24%.

4. The p-type dopant of claim 1, wherein the Group IV semiconductor is a p-type semiconductor and the p-type dopant forms a dopant layer on the p-type semiconductor such that an electric field is induced in the p-type semiconductor, the electric field pointing from the p-type semiconductor to the dopant layer.

5. The p-type dopant of claim 1, wherein the Group IV semiconductor comprises silicon.

6. The p-type dopant of claim 1, wherein the Group IV semiconductor is an n-type semiconductor and the p-type dopant introduces band bending to the n-type Group IV semiconductor causing heterojunction band structures.

7. A method of p-type doping of a Group IV semiconductor; the method comprising the steps of:
a) dissociating and ionizing a feedstock comprising a mixture of nitrogen and phosphorous a using an input power; and
b) applying a bias onto a support for the Group IV semiconductor so that ions from the ionized nitrogen and phosphorous are attracted to and implanted on a surface of the Group IV semiconductor.

8. The method of claim 7, wherein the input power ranges from 2 kW to 3 kW.

9. The method of claim 7, wherein the bias ranges from 150V to 600V.

10. The method of claim 7, wherein percentage of nitrogen in the mixture ranges from 50% to 100%.

11. The method of claim 7, wherein the phosphorous is provided in the form of gaseous phosphine and the nitrogen is provided in the form of gaseous nitrogen.

12. The method of claim 7, wherein the Group IV semiconductor is a p-type silicon layer.

13. The method of claim 7, wherein the Group IV semiconductor is an n-type semiconductor and the p-type dopant introduces band bending to the n-type Group IV semiconductor causing heterojunction band structures.

14. A Group IV semiconductor device comprising:
a Group IV semiconductor layer;
a p-type dopant layer formed on the Group IV semiconductor layer using a dopant comprising a mixture of nitrogen and phosphorous, the p-type dopant layer having shallow-level acceptor complexes contributing holes and a widened bandgap compared to the Group IV semiconductor layer.

15. The Group IV semiconductor device of claim 13, wherein the Group IV semiconductor layer comprises a silicon layer and the p-type dopant layer has no significant decrease in silicon density compared to the silicon layer.

16. The Group IV semiconductor device of claim 13, wherein the device is a silicon solar cell, the Group IV semiconductor layer is a p-type crystalline silicon layer and the p-type dopant layer forms an electric field and an ohmic contact on the p-type crystalline silicon layer.

17. The Group IV semiconductor device of claim 13, wherein the Group IV semiconductor is an n-type semiconductor and the p-type dopant introduces band bending to the n-type Group IV semiconductor causing heterojunction band structures.
